(19) United States
(12) Patent Application Publication
(10) Pub. No.: US 2024/0203769 A1
(43) Pub. Date: Jun. 20, 2024

(54) WAFER EVALUATION METHOD, WAFER PRODUCTION METHOD AND DEVICE PRODUCTION METHOD

(71) Applicant: Resonac Corporation, Tokyo (JP)

(72) Inventor: Ling GUO, Tokyo (JP)

(73) Assignee: Resonac Corporation, Tokyo (JP)

(21) Appl. No.: 18/538,445

(22) Filed: Dec. 13, 2023

(30) Foreign Application Priority Data
Dec. 15, 2022 (JP) 2022-200111

(51) Int. Cl. H01L 21/67; G01N 7/00; H01L 21/02; H01L 21/66

(52) U.S. Cl. CPC H01L 21/67288; H01L 21/02002; H01L 21/02378; H01L 22/12; G01N 7/00

(57) ABSTRACT

A wafer evaluation method according to the present embodiment includes installing a SiC wafer or a SiC epitaxial wafer on a porous plate having a plurality of through holes; installing a lid on a second surface opposite to a first surface of the SiC wafer or the SiC epitaxial wafer with an O-ring therebetween; supplying a gas into a space surrounded by the second surface, the O-ring and the lid and pressurizing the inside of the space; and measuring the pressure in the space after a certain period has elapsed and inspecting whether there is a threading defect in the SiC wafer or the SiC epitaxial wafer.

### BACKGROUND

### Field

The present disclosure relates to a wafer evaluation method, a wafer production method and a device production method. Priority is claimed on Japanese Patent Application No. 2022-200111, filed Dec. 15, 2022, the contents of which are incorporated herein by reference.

### Description of Related Art

Compared to silicon (Si), silicon carbide (SiC) has an insulation breakdown electric field that is one order of magnitude larger and a band gap which is three times thereof. In addition, silicon carbide (SiC) has characteristics such as a thermal conductivity that is about three times that of silicon (Si). Therefore, silicon carbide (SiC) is expected to be able to be applied to power devices, high frequency devices, high temperature operation devices, and the like. Therefore, in recent years, SiC epitaxial wafers have been used for semiconductor devices such as those mentioned above.

A SiC epitaxial wafer is obtained by laminating a SiC epitaxial layer on a surface of a SiC wafer. Hereinafter, a wafer before the SiC epitaxial layer is laminated will be referred to as the SiC wafer, and a wafer after the SiC epitaxial layer is laminated will be referred to as the SiC epitaxial wafer. The SiC wafer is cut out from a SiC ingot.

The SiC wafer is produced by cutting out a SiC ingot. Defects in SiC wafers have an adverse effect on SiC epitaxial wafers and SiC devices. A threading defect is one defect that greatly affects SiC epitaxial wafers and SiC devices. In addition, SiC devices having the threading defect may cause breakdown voltage defects.

It is difficult to reliably detect threading defects that adversely affect devices, and various methods have been proposed. For example, in Patent Document 1 and Patent Document 2, threading defects are identified by comparing the positional relationship, shape and the like of defects in two or more SiC wafers cut out from the same ingot. In addition, for example, in Patent Document 3, when a liquid is applied to a SiC wafer and the applied surface and a surface opposite thereto are vacuum-suctioned, it is checked whether there is a threading defect.

### PATENT DOCUMENTS

[Patent Document 1] Japanese Unexamined Patent Application, First Publication No. 2022-66972

[Patent Document 2] Japanese Unexamined Patent Application, First Publication No. 2001-40004

[Patent Document 3] Japanese Unexamined Patent Application, First Publication No. 2006-286693

### SUMMARY

In threading defect evaluating methods described in Patent Document 1 and Patent Document 2, it is necessary to prepare another SiC wafer cut out from the same ingot. In addition, in a threading defect evaluating method described in Patent Document 3, liquid application is necessary and the operation is complicated.

The present disclosure has been made in view of the above circumstances, and an object of the present disclosure is to provide a wafer evaluation method, a wafer production method and a device production method through which it is possible to efficiently detect threading defects at low cost.

The inventors found that, when pressurization inspection is performed, it is possible to appropriately identify the presence of threading defects in a SiC wafer or a SiC epitaxial wafer. The present disclosure provides the following aspects in order to address the above problems.
(1) A wafer evaluation method according to a first aspect includes installing a SiC wafer or a SiC epitaxial wafer on a porous plate having a plurality of through holes; installing a lid on a second surface opposite to a first surface of the SiC wafer or the SiC epitaxial wafer with an O-ring therebetween; supplying a gas into a space surrounded by the second surface, the O-ring and the lid and pressurizing the inside of the space; and measuring the pressure in the space after a certain period has elapsed and inspecting whether there is a threading defect in the SiC wafer or the SiC epitaxial wafer.
(2) In the wafer evaluation method according to the above aspect, the initial pressure in the space immediately after the gas is supplied may be 0.2 MPa or more.
(3) In the wafer evaluation method according to the above aspect, the initial pressure in the space immediately after the gas is supplied may be 0.3 MPa or less.
(4) In the wafer evaluation method according to the above aspect, when the difference between the initial pressure in the space immediately after the gas is supplied and the holding pressure in the space after a certain period has elapsed is more than 1/100 of the initial pressure, it may be determined that there is the threading defect.
(5) In the wafer evaluation method according to the above aspect, the O-ring may have an inner diameter of 80 mm or less.
(6) In the wafer evaluation method according to the above aspect, the wafer is the SiC wafer.
(7) In the wafer evaluation method according to the above aspect, the wafer is the SiC epitaxial wafer.
(8) A wafer production method according to a second aspect includes an evaluation process using the wafer evaluation method according to the above aspect.
(9) The wafer production method according to the above aspect may further include an image screening process for checking whether there is the threading defect. The image screening process is performed before the evaluation process.
(10) In the wafer production method according to the above aspect, the evaluation process may include a screening process for screening a wafer having the threading defect with an area of larger than 0 μm² and 182 μm² or less when it is determined that there is the threading defect in the image screening process.
(11) A device production method according to a third aspect includes an evaluation process using the wafer evaluation method according to the above aspect.
(12) The device production method according to the above aspect may further include an image screening process for checking whether there is the threading defect. The image screening process is performed before the evaluation process.
(13) The device production method according to the above aspect may further include a device producing process. The evaluation process includes a screening process for screening a wafer having the threading defect with an area of larger than 0 μm² and 182 μm² or less when it is determined that there is the threading defect in the image screening process. In the device producing process, a device is produced using a wafer having the threading defect with an area of larger than 0 μm² and 182 μm² or less.

According to the wafer evaluation method, the wafer production method and the device production method according to the above aspects, it is possible to efficiently detect threading defects at low cost.

### BRIEF DESCRIPTION OF THE DRAWINGS

FIG. 1 is a cross-sectional view of a SiC wafer evaluation device for illustrating a SiC wafer evaluation method according to a first embodiment.

FIG. 2 is a plan view of the SiC wafer evaluation device for illustrating the SiC wafer evaluation method according to the first embodiment.

FIG. 3 is a diagram showing the evaluation results of Example 1.

FIG. 4 is a diagram showing the evaluation results of Example 2.

FIG. 5 is a diagram showing the evaluation results of Example 3.

FIG. 6 is a diagram showing the evaluation results of Example 4.

FIG. 7 shows diagrams of a SiC wafer of Sample 8 measured under a confocal differential interference microscope.

FIG. 8 shows diagrams of a SiC wafer of Sample 9 measured under a confocal differential interference microscope.

FIG. 9 is an X-ray CT image of a cross section of the SiC wafer of Sample 8.

FIG. 10 is a diagram of a cross section of the SiC wafer of Sample 8 measured under a confocal differential interference microscope.

FIG. 11 is an X-ray CT image of a cross section of the SiC wafer of Sample 9.

FIG. 12 is a diagram of the cross section of the SiC wafer of Sample 9 measured under a confocal differential interference microscope.

FIG. 13 shows an X-ray computed tomography (CT) image of a cross section of a SiC epitaxial wafer of Sample 10 and a confocal differential interference microscope image of a SiC wafer.

### DETAILED DESCRIPTION

Hereinafter, the present embodiment will be appropriately described in detail with reference to the drawings. In the drawings used in the following description, in order to facilitate understanding of features of the present embodiment, characteristic parts are enlarged for convenience of illustration in some cases, and the dimensional proportions of components may be different from actual components. Materials, sizes and the like exemplified in the following descriptions are examples, the present disclosure is not limited thereto, and can be appropriately changed and implemented within ranges without changing the scope and spirit of the disclosure.

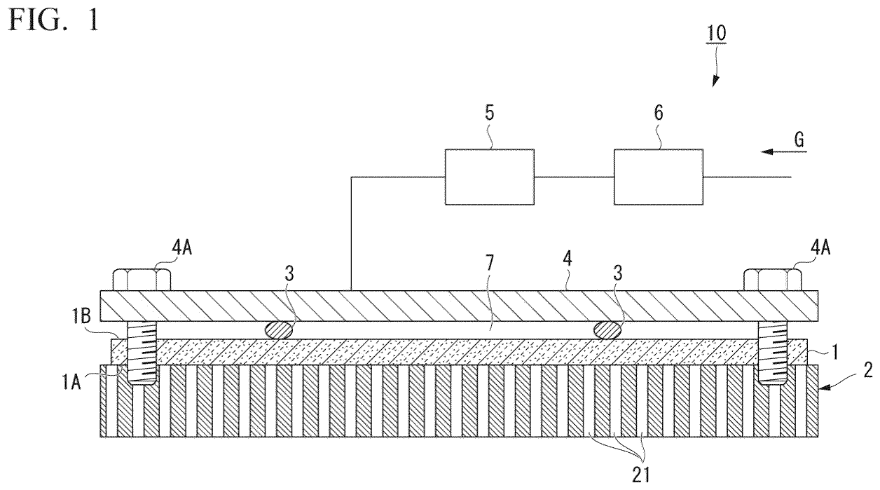

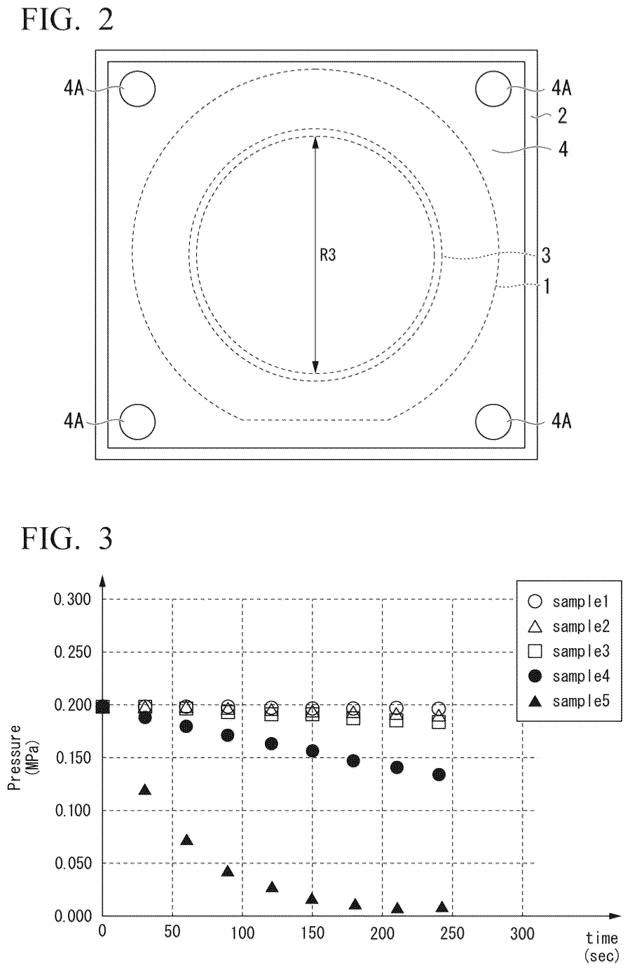

FIG. 1 cross-sectional view of a SiC wafer evaluation device for illustrating a SiC wafer evaluation method according to a first embodiment. FIG. 2 is a plan view of the SiC wafer evaluation device for illustrating the SiC wafer evaluation method according to the first embodiment. An evaluation device 10 is used to evaluate whether there is a threading defect in a SiC wafer 1. Hereinafter, an example in which an evaluation target is the SiC wafer 1 will be described, but the evaluation target may be a SiC epitaxial wafer. That is, the SiC wafer 1 in FIG. 1 and FIG. 2 can be replaced with a SiC epitaxial wafer, and the SiC wafer 1 in the following description can be replaced with a SiC epitaxial wafer.

The evaluation device 10 includes a porous plate 2, an O-ring 3, a lid 4, a pressure gauge 5 and a regulator 6.

The porous plate 2 has a plurality of through holes 21. Each of the plurality of through holes 21 penetrates between a first surface and a second surface of the porous plate 2. As the porous plate 2, a known plate can be used. For example, the porous plate 2 is made of alumina, and has a pore diameter of 2 μm, a porosity of 40%, and a hardness (HRH scale) of 90. For example, in a plan view, the porous plate 2 is larger than the O-ring 3.

When the SiC wafer 1 is evaluated, the SiC wafer 1 is installed on the porous plate 2 with a first surface 1A of the SiC wafer 1 that faces down. The SiC wafer 1 is installed so that the direction in which the plurality of through holes 21 of the porous plate 2 extend intersects with the first surface 1A of the SiC wafer 1.

The O-ring 3 and the lid 4 are arranged on the side of a second surface 1B of the SiC wafer 1. The second surface 1B is a surface opposite to the first surface 1A. The O-ring 3 is interposed between the lid 4 and the SiC wafer 1. The O-ring 3 is in close contact with the lid 4 and the SiC wafer 1.

An inner diameter R3 of the O-ring 3 is, for example, 80 mm or less. When the inner diameter R3 of the O-ring 3 is narrower, the volume of a space 7 becomes smaller and the detection sensitivity of threading defects in the SiC wafer 1 becomes higher. The space 7 is a space surrounded by the second surface 1B of the SiC wafer 1, the O-ring 3 and the lid 4.

The lid 4 is not particularly limited as long as it does not allow air to pass through. The lid 4 is, for example, a resin plate, a metal plate or the like. For example, the lid 4 is larger than the O-ring 3 in a plan view. The lid 4 covers the upper surface of the O-ring 3 and forms the space 7. The lid 4 faces the second surface 1B with the O-ring 3 therebetween. On the upper surface of the lid 4, for example, a restraining member 4A is installed. The restraining member 4A prevents the lid 4 from coming off when the space 7 is pressurized. The restraining member 4A is, for example, a handle screw having a screw part, and the screw part is screwed into the porous plate.

The pressure gauge 5 and the regulator 6 are connected to the space 7. The pressure gauge 5 measures the pressure in the space 7. The regulator 6 adjusts the pressure in the space 7. As the pressure gauge 5 and the regulator 6, known ones can be used.

A gas G is supplied into the space 7. The gas G is, for example, air, nitrogen, argon or the like. When the gas G is supplied to the space 7, the inside of the space 7 is pressurized. When the pressure in the space 7 reaches a certain pressure, supply of the gas G into the space 7 is stopped. The pressure in the space 7 when supply of the gas G into the space 7 is stopped is referred to as an initial pressure.

The initial pressure in the space 7 is, for example, 0.1 MPa or more, preferably 0.15 MPa or more, and more preferably 0.2 MPa or more. If the initial pressure in the space 7 is higher, the detection sensitivity of threading defects in the SiC wafer 1 is higher.

In addition, the initial pressure in the space 7 is, for example, 0.3 MPa or less, and preferably 0.2 MPa or less. If the initial pressure of the space 7 is high, the O-ring 3 may stick to the SiC wafer 1. If the O-ring 3 and the SiC wafer 1 stick together, it is difficult to separate them, and when they are separated, the SiC wafer 1 may be damaged. When the initial pressure of the space 7 is prevented from increasing too high, it is possible to prevent the O-ring 3 and the SiC wafer 1 from sticking together. For example, if the initial pressure is 0.2 MPa or less and the inner diameter of the O-ring 3 is 80 mm, the O-ring 3 does not stick to the SiC wafer 1. If the initial pressure is lower and the inner diameter of the O-ring 3 is smaller, the O-ring 3 and the SiC wafer 1 are less likely to stick together. In addition, if the initial pressure is 0.1 MPa, the O-ring 3 and the SiC wafer 1 do not stick together, regardless of the diameter of the O-ring 3.

The pressure in the space 7 is measured with the pressure gauge 5. The pressure in the space 7 is monitored for a certain period after supply of the gas G is stopped. The certain period can be appropriately set depending on the pressure in the space 7, and the volume of the space 7. For example, the pressure in the space 7 may be monitored for 240 seconds or may be monitored for 60 seconds. The pressure in the space 7 after a certain period has elapsed since supply of the gas G into the space 7 is stopped is referred to as a holding pressure.

In the SiC wafer evaluation method according to the first embodiment, when the holding pressure in the space 7 is measured, it is determined whether the SiC wafer 1 has a threading defect.

When the SiC wafer 1 has no threading defect, the space 7 is a blocked space surrounded by the second surface 1B of the SiC wafer 1, the O-ring 3 and the lid 4. Even if there is a slight leak from around the O-ring 3, the holding pressure in the space 7 does not significantly drop from the initial pressure after a certain period has elapsed.

On the other hand, when the SiC wafer 1 has a threading defect, the gas G in the space 7 leaks to the outside through the threading defect and the through hole 21. Therefore, the holding pressure in the space 7 decreases from the initial pressure after a certain period has elapsed. Here, the position of the threading defect in the SiC wafer 1 may deviate from the position of the through hole of the porous plate 2. Even if the position of the threading defect of the SiC wafer 1 deviates from the position of the through hole of the porous plate 2, the gas G in the space 7 leaks to the outside. For example, the gas G in the space 7 passes through a small gap between the SiC wafer 1 and the porous plate 2 from the threading defect, and additionally passes through the through hole 21, and leaks to the outside.

The holding pressure that is a threshold value for determination can be appropriately set depending on the quality required for the SiC wafer 1, the initial pressure of the space 7, setting conditions for a certain period and the like. For example, when the difference between the initial pressure and the holding pressure is 1/100 or less of the initial pressure, it is determined that the SiC wafer 1 does not have a problematic threading defect, and when the difference between the initial pressure and the holding pressure exceeds 1/100 of the initial pressure, it is determined that the SiC wafer 1 has a problematic threading defect. For example, if the initial pressure is 0.2 MPa, when the holding pressure is 0.198 MPa or more and the difference between the initial pressure and the holding pressure is 0.002 MPa or less, it is determined that the SiC wafer 1 has no threading defect, and when the holding pressure is less than 0.198 MPa and the difference between the initial pressure and the holding pressure is more than 0.002 MPa, it is determined that the SiC wafer 1 has a threading defect. Here, even if the SiC wafer 1 has a threading defect that does not adversely affect the quality of devices and a device producing process, since this defect does not have an adverse effect, there is no problem even if it is determined that it has no threading defect.

As described above, in the SiC wafer evaluation method according to the first embodiment, when the inside of the space 7 is pressurized and the change in the pressure in the space 7 is measured, it is possible to determine whether there is a problematic threading defect in the SiC wafer 1 in the subsequent process.

In addition, the SiC wafer evaluation method according to the first embodiment can be incorporated as one process in a SiC wafer production method, a SiC epitaxial wafer production method and a SiC device production method.

For example, when incorporated into the SiC wafer production method, an evaluation process using the evaluation method is performed after a SiC wafer is cut out from an ingot and before a SiC epitaxial film is formed on a SiC wafer. In the evaluation process, first, it is determined whether there is a threading defect. When the evaluation process is performed, the SiC wafer 1 that may be defective can be screened early and the yield of the device can be increased.

In addition, for example, when incorporated into the SiC epitaxial wafer and SiC device production method, an evaluation process using the evaluation method is performed after a SiC epitaxial film is formed on a SiC wafer. In the evaluation process, first, it is determined whether there is a threading defect. When the evaluation process is performed, the SiC epitaxial wafer that may be defective can be screened early, and the yield of the device can be increased.

The SiC wafer evaluation method may be performed on all SiC wafers cut out from an ingot or may be performed on a screened specific SiC wafer. Specific SiC wafer screening can be performed by, for example, image screening. That is, the SiC wafer evaluation method according to the first embodiment may be performed after an image screening process is performed.

The image screening process can be performed, for example, under an optical microscope that can observe the surface of the SiC wafer. In the image screening process, a first screening process and a second screening process may be performed.

In the first screening process, the size of the defect is measured. In the first screening process, it is screened whether a first condition in which the size of the defect is a predetermined area or more is satisfied. The predetermined area is, for example, 300 μm². The size of the defect can be calculated from an optical microscope image. If there is a defect that satisfies the first condition in the SiC wafer in the first screening process, the process proceeds to the second screening process. If there is no defect that satisfies the first condition in the SiC wafer in the first screening process, it can be determined that the SiC wafer does not have a threading defect that adversely affects devices, and the SiC wafer evaluation method according to the first embodiment may not be performed.

In the second screening process, the positions of the defects and the SN ratios in SiC wafers cut out from ingots grown from the same seed crystal are compared. In the second screening process, for example, the method described in Patent Document 1 can be used. If it is determined that there is a threading defect in the SiC wafer in the second screening process, the SiC wafer evaluation method according to the first embodiment is performed. If it is determined that it has no threading defect in the SiC wafer in the second screening process, it can be determined that the SiC wafer does not have a threading defect that adversely affects devices, and the SiC wafer evaluation method according to the first embodiment may not be performed.

When the image screening process is performed, it is not necessary to perform the SiC wafer evaluation method according to the first embodiment to all SiC wafers, and the SiC epitaxial wafer production method and the SiC device production method can be made efficient. Similarly, the image screening process may be performed on the SiC epitaxial wafer.

In addition, the SiC wafer evaluation method according to the first embodiment will be described below in detail, but the threading defect can be evaluated with higher accuracy than when a leak check is performed using He. In addition, some threading defects may become blocked during growth and have little effect on the device. In the SiC wafer evaluation method according to the first embodiment, since a SiC wafer having a blocked threading defect that does not become a no good (NG) defect is not determined as NG, it is possible to reduce the number of SiC wafers 1 that are determined to be defective even though they do not adversely affect devices.

In addition, for example, first, in the image screening process, it is checked whether there is a threading defect, and the wafer evaluation process in the first embodiment may be performed on a wafer that is confirmed to have a threading defect. In this process, for example, when the O-ring 3 with an inner diameter of 80 mm is used, a wafer having a threading defect with an area of 182 μm² or less can be screened. That is, a wafer having a threading defect with an area of more than 0 μm² and 182 μm² or less can be screened. Wafers having a threading defect with an area of 182 μm² or less include wafers with blocked threading defects. When the area of the threading defect is 182 μm² or less, there is a low possibility of it adversely affecting subsequent processes. When the wafer evaluation process in the first embodiment is performed after the image screening process, it is possible to reduce the number of SiC wafers 1 that are determined to be defective even though they do not adversely affect devices.

While preferable embodiments of the present invention have been described above in detail, the present invention is not limited to these specific embodiments, and various modifications and alternations can be made in a range within the spirit and scope of the present invention described in the scope of the claims.

### EXAMPLES

### Example 1

A plurality of SiC wafers with a diameter of 150 mm (6-inch) were prepared. Each SiC wafer was observed using an inspection device (commercially available from Lasertec Corporation, a device having the same principle as SICA88) having a confocal differential interference microscope and a photoluminescence (PL) observation function, and it was checked whether there was a threading defect. Sample 1 was a SiC wafer in which no threading defect was confirmed. In addition, Sample 2 to Sample 5 were SiC wafers in which a threading defect was confirmed.

Then, in each of Sample 1 to Sample 5, it was evaluated whether there was a threading defect using the evaluation device 10 shown in FIG. 1 and FIG. 2. In the evaluation using the evaluation device 10, the initial pressure in the space 7 was 0.2 MPa. In addition, the diameter of the O-ring 3 was 80 mm. Then, the holding pressure in the space 7 was measured 240 seconds after supply of a gas into the space 7 was stopped. The evaluation results of Example 1 are summarized in FIG. 3. In the graph shown in FIG. 3, the horizontal axis represents the time that has elapsed since gas supply was stopped, and the vertical axis represents the pressure in the space 7. In addition, the holding pressures in the space 7 when the samples were evaluated are as follows.
Sample 1: 0.198 MPa
Sample 2: 0.197 MPa
Sample 3: 0.183 MPa
Sample 4: 0.135 MPa
Sample 5: 0.007 MPa

In Sample 1 having no threading defect, the pressure in the space 7 hardly changed. In Sample 1, the holding pressure was 0.198 MPa, and the difference between the initial pressure and the holding pressure was 0.002 MPa. The difference between the initial pressure and the holding pressure in the evaluation of Sample 1 was thought to be due to leakage from the O-ring. On the other hand, in Sample 2 to Sample 5, the holding pressure was less than 0.198 MPa and the difference between the initial pressure and the holding pressure was more than 0.002 MPa. That is, when a line in which the holding pressure after 240 seconds was 0.198 MPa was set as a threshold, it was possible to evaluate whether there was a threading defect in the SiC wafer.

### Example 2

In Example 2, the correlation between the size of the threading defect and the holding pressure was confirmed. In Example 2, in the evaluation using the evaluation device 10, the initial pressure in the space 7 was 0.2 MPa. In addition, the diameter of the O-ring 3 was 80 mm. Then, when it was confirmed that there was only one threading defect within the measurement region, the area of the threading defect was measured. Then, the holding pressure in the space 7 was measured 60 seconds after supply of a gas into the space 7 was stopped.

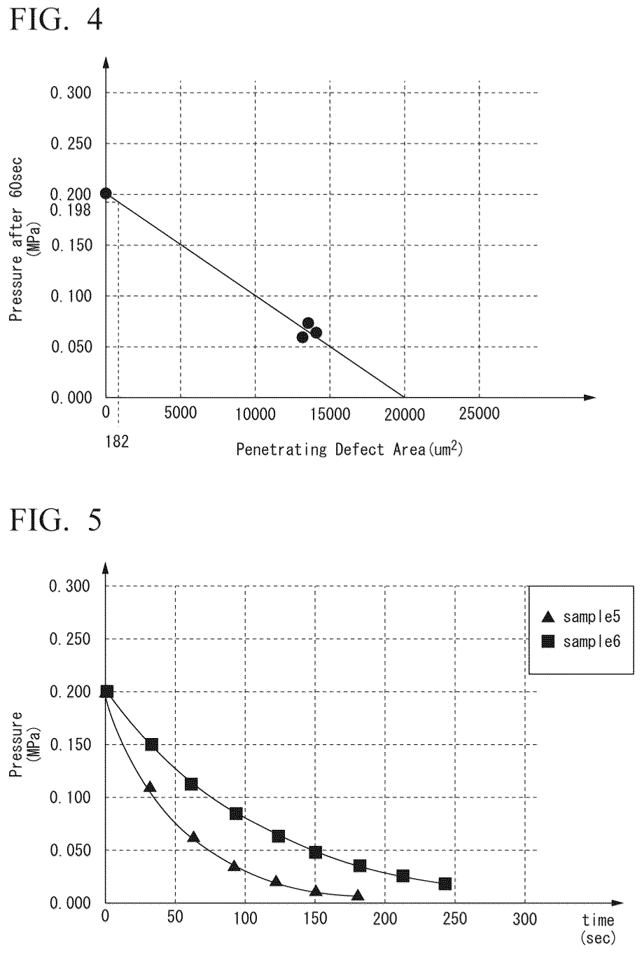

FIG. 4 is a diagram showing the evaluation results of Example 2. In FIG. 4, the horizontal axis represents the area of the threading defect. The area of the threading defect was the area on the second surface of the SiC wafer. In FIG. 4, the vertical axis represents the holding pressure in the space 7 60 seconds after supply of a gas was stopped. As shown in FIG. 4, it was confirmed that there was a correlation between the area of the threading defect and the holding pressure.

In addition, as shown in Example 1, when the holding pressure in the space after 60 seconds was 0.198 MPa or more, it was difficult to distinguish leaks from the O-ring and leaks from the threading defect and it was difficult to determine using this evaluation method. That is, when the area of the threading defect was 182 μm² or less, it was difficult to determine whether it was a threading defect. On the other hand, the minimum area of the threading defect that causes leakage of a developer or the like during device production was about 300 μm². Therefore, the threading defect of 182 μm² or less had a low possibility of adversely affecting the quality of devices and a device production process, and was not a problem even if it could not be measured. Here, an example in which the threshold value for determination was 182 μm² was shown, but by increasing the pressure in the space and lengthening a certain period before the holding pressure was measured, it was possible to evaluate a threading defect of 182 μm² or less. Here, in the calculation in FIG. 4, the area of the threading defect could be thought of as the cross-sectional area of the threading defect.

### Example 3

In Example 3, the diameter of the O-ring was changed, and the relationship between the measurement range (the volume of the space) and the change in pressure in the space was determined. Sample 5 in Example 3 was the same as Sample 5 in Example 1, and evaluated under the same conditions. Sample 6 in Example 3 differed from Sample 5 in that the diameter of the O-ring was 150 mm and the entire surface of the SiC wafer was covered. The other items in the evaluation conditions for Sample 6 were the same as those for Sample 5. In addition, the same SiC wafer to be evaluated was used for Sample 5 and Sample 6.

FIG. 5 is a diagram showing the evaluation results of Example 3. In FIG. 5, the horizontal axis represents the time that has elapsed since gas supply was stopped. In FIG. 5, the vertical axis represents the pressure in the space 7. As shown in FIG. 5, if the measurement range was narrower, the pressure drop speed in the space 7 was faster. That is, if the measurement range was narrower, the detection sensitivity of the threading defect was higher.

### Example 4

In Example 4, the pressure in the space was changed, and the relationship between pressurization conditions in the space and the change in pressure in the space was determined. Sample 5 in Example 4 was the same as Sample 5 in Example 1, and evaluated under the same conditions. Sample 7 in Example 4 differed from Sample 5 in that the initial pressure in the space was 0.1 MPa. The other items in the evaluation conditions for Sample 7 were the same as those for Sample 5. In addition, the same SiC wafer to be evaluated was used for Sample 5 and Sample 7.

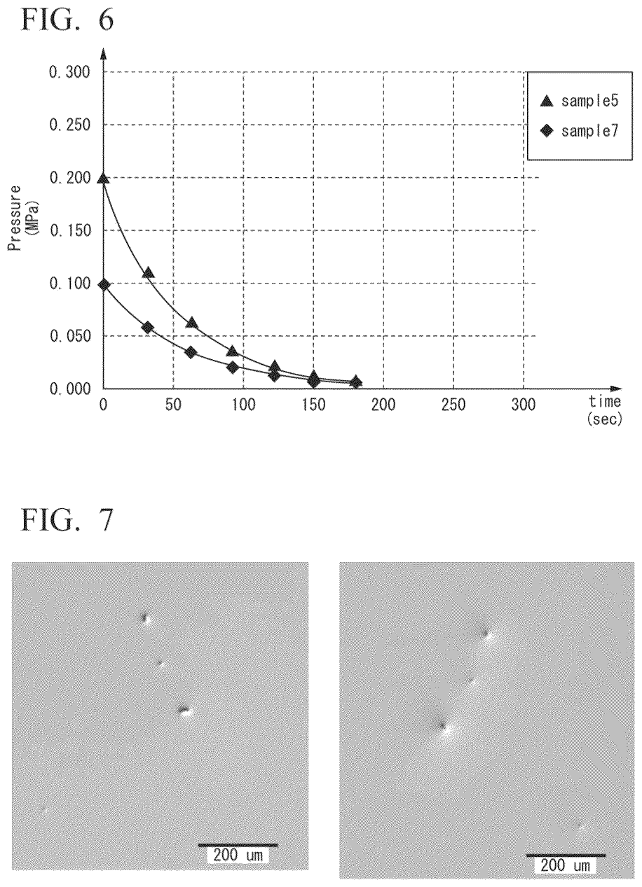

FIG. 6 is a diagram showing the evaluation results of Example 4. In FIG. 6, the horizontal axis represents the time that has elapsed since gas supply was stopped. In FIG. 6, the vertical axis represents the pressure in the space 7. As shown in FIG. 6, if the initial pressure in the space was higher, the pressure drop speed in the space was faster. That is, if the initial pressure was higher, the detection sensitivity of the threading defect was higher. On the other hand, if the initial pressure in the space was too high, there was a problem of the O-ring and the SiC wafer adhering together, making it difficult to separate them.

### Example 5

In Example 5, two SiC wafers of Sample 8 and Sample 9 were prepared and these were evaluated. In Sample 8, the holding pressure 240 seconds after supply of a gas into the space was stopped was 0.198 MPa. On the other hand, in Sample 9, the holding pressure 240 seconds after supply of a gas into the space was stopped was 0.196 MPa.

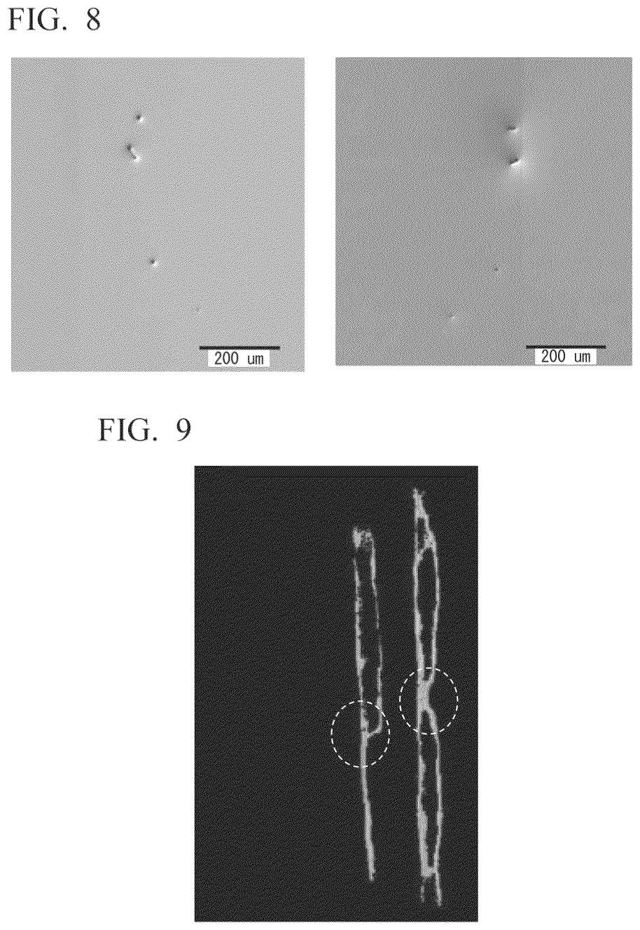

FIG. 7 shows diagrams of the SiC wafer of Sample 8 measured under a confocal differential interference microscope. The left diagram in FIG. 7 is an image of a first surface of the SiC wafer, and the right diagram in FIG. 7 is an image of a second surface of the SiC wafer. On the other hand, FIG. 8 shows diagrams of the SiC wafer of Sample 9 measured under a confocal differential interference microscope. The left diagram in FIG. 8 is an image of a first surface of the SiC wafer, and the right diagram in FIG. 8 is an image of a second surface of the SiC wafer. Both Sample 8 and Sample 9 had defects at positions corresponding to the front and back surfaces, which were thought to be threading defects.

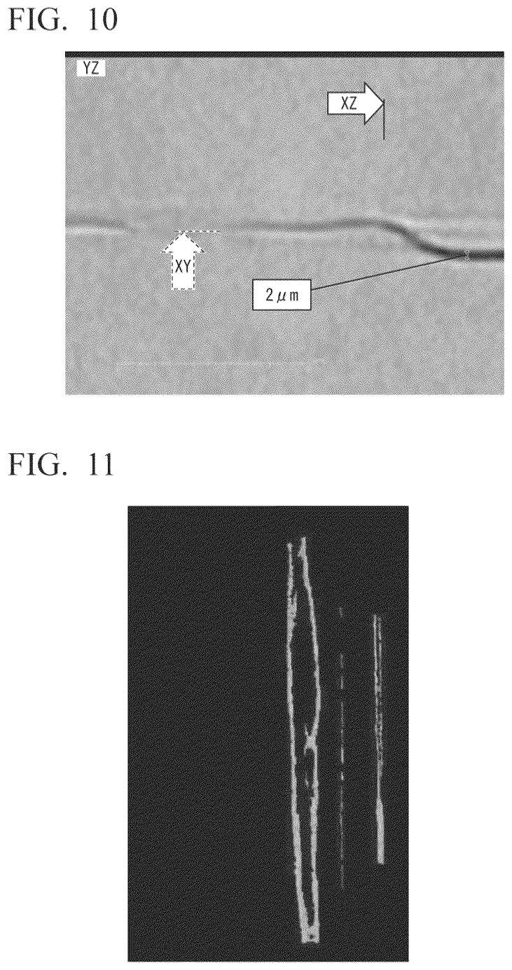

FIG. 9 is an X-ray computed tomography (CT) image of a cross section of the SiC wafer of Sample 8. In addition, FIG. 10 is a diagram of a cross section of the SiC wafer of Sample 8 measured under a confocal differential interference microscope. The cross section in FIG. 9 and FIG. 10 was the cross section of the defect shown in FIG. 7.

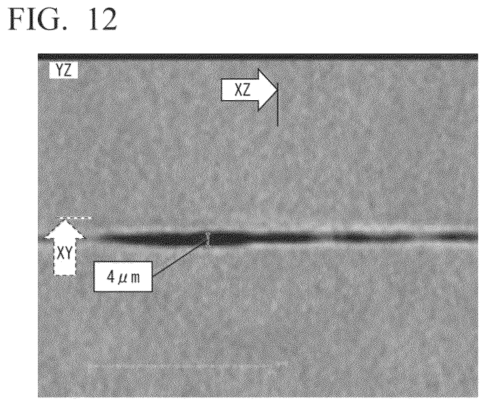

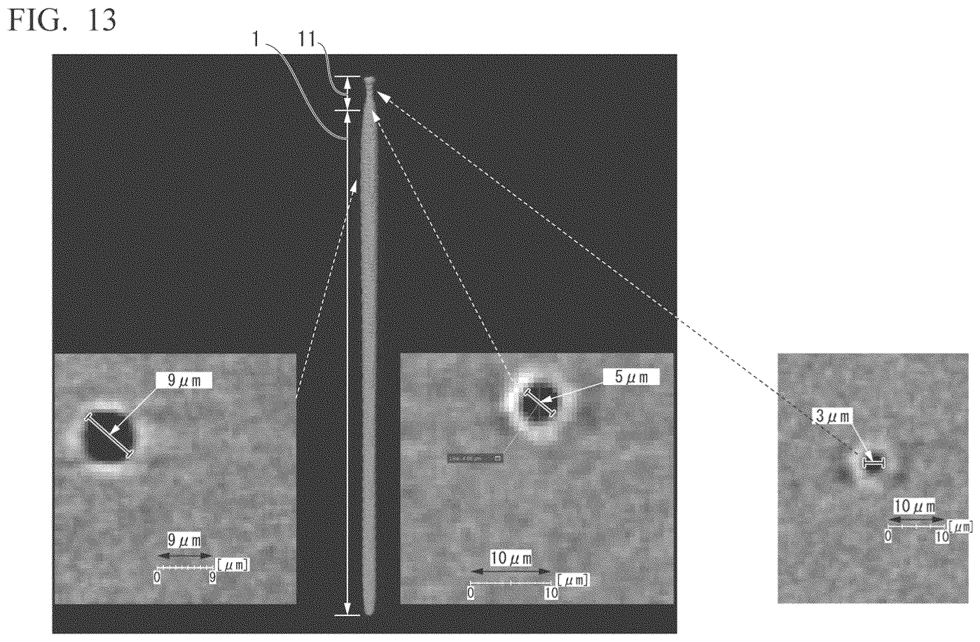

In addition, FIG. 11 is an X-ray computed tomography (CT) image of a cross section of the SiC wafer of Sample 9. In addition, FIG. 12 is a diagram of the cross section of the SiC wafer of Sample 9 measured under a confocal differential interference microscope. The cross section in FIG. 11 and FIG. 12 was the cross section of the defect shown in FIG. 8.

As shown in FIG. 9, in the SiC wafer of Sample 8, threading defects were blocked in regions surrounded by the dotted line. FIG. 10 shows an enlarged view of the part, and it was confirmed that holes did not communicate and were separated. On the other hand, as shown in FIG. 11, in the SiC wafer of Sample 9, no threading defect blocking was confirmed. In FIG. 12, it was confirmed that holes were in communication.

In Sample 8 and Sample 9, the same defect appeared in the surface image. However, as shown in FIG. 9 and FIG. 10, the defect of Sample 8 was blocked, but as shown in FIG. 11 and FIG. 12, the defect of Sample 9 was communicated. The difference in the results of evaluation using the evaluation method according to the present embodiment was thought to be due to the shape of the defect.

That is, in the SiC wafer evaluation method according to the present embodiment, the difference in the internal shape of threading defects that cannot be detected by surface observation alone can also be evaluated.

### Example 6

In Example 6, a SiC wafer was prepared, and Sample 10 was prepared by forming a SiC epitaxial film with a thickness of 10 μm on one surface of the SiC wafer and evaluated. In Sample 10, the holding pressure 240 seconds after supply of a gas into the space was stopped was 0.197 MPa.

FIG. 13 shows an X-ray computed tomography (CT) image of a cross section of the SiC epitaxial wafer of Sample 10 and a confocal differential interference microscope image of the SiC wafer. As shown in FIG. 13, the threading defect communicating between the SiC wafer 1 and a SiC epitaxial film 11 was confirmed. The diameter of the threading defect in the SiC wafer 1 was about 9 μm, about 5 μm at the interface between the SiC wafer 1 and the SiC epitaxial film 11, and about 3 μm within the SiC epitaxial film 11. For example, when the threading defect was cylindrical and had a diameter of about 3 μm, the cross-sectional area was about 7 μm². It can be understood that the diameter of the threading defect was reduced when the SiC epitaxial film 11 was formed in FIG. 13.

As shown in Example 6, the SiC wafer evaluation method according to the present embodiment could be applied as a SiC epitaxial wafer evaluation method. In addition, even if the minimum diameter of the threading defect was 3 μm, the threading defect could be evaluated using the evaluation method according to the present embodiment.

### Example 7

In Example 7, a plurality of samples in which liquid leakage occurred in a developer application process during device production were prepared even though the samples passed the He leak check. The He leak check was a method in which a SiC wafer was vacuum-chucked into a chamber via an O-ring, and the presence of pinholes was determined based on whether helium gas ejected to the surface of the SiC wafer could be detected from the back surface. If the amount of leakage when He was sprayed onto the surface of the SiC wafer was 10 times or less the amount of leakage before spraying, it was determined that the sample passed the He leak check.

Using the SiC wafer evaluation method according to the present embodiment, these samples were evaluated. The conditions for evaluating the samples were the same as the conditions for Example 1. As a result, the holding pressure of all the samples was less than 0.198 MPa. That is, in the SiC wafer evaluation method according to the present embodiment, all of these samples were determined to be NG. That is, in the SiC wafer evaluation method according to the present embodiment, the threading defect could be measured with higher sensitivity than that of the He leak check.

### EXPLANATION OF REFERENCES

1 SiC wafer
1A First surface
1B Second surface
2 Porous plate
3 O-ring
4 Lid
5 Pressure gauge
6 Regulator
7 Space
10 Evaluation device
11 SiC epitaxial film
21 Through hole

What is claimed is:

1. A wafer evaluation method, comprising:
installing a SiC wafer or a SiC epitaxial wafer on a porous plate having a plurality of through holes;
installing a lid on a second surface opposite to a first surface of the SiC wafer or the SiC epitaxial wafer with an O-ring therebetween;
supplying a gas into a space surrounded by the second surface, the O-ring and the lid and pressurizing the inside of the space; and
measuring the pressure in the space after a certain period has elapsed and inspecting whether there is a threading defect in the SiC wafer or the SiC epitaxial wafer.

2. The wafer evaluation method according to claim 1,
wherein the initial pressure in the space immediately after the gas is supplied is 0.2 MPa or more.

3. The wafer evaluation method according to claim 1,
wherein the initial pressure in the space immediately after the gas is supplied is 0.3 MPa or less.

4. The wafer evaluation method according to claim 1,
wherein, when the difference between the initial pressure in the space immediately after the gas is supplied and the holding pressure in the space after a certain period has elapsed is more than 1/100 of the initial pressure, it is determined that there is the threading defect.

5. The wafer evaluation method according to claim 1,
wherein the O-ring has an inner diameter of 80 mm or less.

6. The wafer evaluation method according to claim 1,
wherein the wafer is the SiC wafer.

7. The wafer evaluation method according to claim 1,
wherein the wafer is the SiC epitaxial wafer.

8. A wafer production method, comprising
an evaluation process using the wafer evaluation method according to claim 1.

9. The wafer production method according to claim 8, further comprising
an image screening process for checking whether there is the threading defect,
wherein the image screening process is performed before the evaluation process.

10. The wafer production method according to claim 9,
wherein the evaluation process includes a screening process for screening a wafer having the threading defect with an area of larger than 0 μm² and 182 μm² or less when it is determined that there is the threading defect in the image screening process.

11. A device production method, comprising
an evaluation process using the wafer evaluation method according to claim 1.

12. The device production method according to claim 11, further comprising
an image screening process for checking whether there is the threading defect,
wherein the image screening process is performed before the evaluation process.

13. The device production method according to claim 12, further comprising a device producing process,
wherein the evaluation process includes a screening process for screening a wafer having the threading defect with an area of larger than 0 μm² and 182 μm² or less in the evaluation process when it is determined that there is the threading defect in the image screening process, and
wherein, in the device producing process, a device is produced using a wafer having the threading defect with an area of larger than 0 μm² and 182 μm² or less.
